(19) United States
(12) Patent Application Publication
(10) Pub. No.: US 2025/0382694 A1
(43) Pub. Date: Dec. 18, 2025

(54) DEPOSITION MASK AND MANUFACTURING METHOD FOR FORMING A DISPLAY PANEL PATTERN USING THE SAME

(71) Applicant: Samsung Display Co., LTD., Yongin-si (KR)

(72) Inventors: Sung Woon KIM, Yongin-si (KR); Duck Jung LEE, Yongin-si (KR)

(21) Appl. No.: 19/043,445

(22) Filed: Feb. 1, 2025

(30) Foreign Application Priority Data
Jun. 17, 2024 (KR) 10-2024-0077990

(51) Int. Cl. C23C 14/04

(52) U.S. Cl. CPC C23C 14/042

(57) ABSTRACT

A deposition mask includes a substrate including a plurality of cell regions, a mask lip region partitioning the plurality of cell regions, and an outer frame region disposed at an outer edge of the plurality of cell regions; a mask membrane defined by an inorganic film pattern which is a portion of an inorganic film formed on the substrate and disposed to correspond to the plurality of cell regions; and a dummy inorganic film pattern which is a remaining portion of the inorganic film except for the inorganic film pattern, where the dummy inorganic film pattern includes a first dummy inorganic film pattern disposed in the mask lip region, and a second dummy inorganic film pattern disposed in a portion of the outer frame region, and the first dummy inorganic film pattern includes a lip opening exposing a surface of the substrate in the mask lip region.

This application claims priority to Korean Patent Application No. 10-2024-0077990, filed on Jun. 17, 2024, and all the benefits accruing therefrom under 35 U.S.C. § 119, the content of which in its entirety is herein incorporated by reference.

### BACKGROUND

### 1. Field

The disclosure relates to a deposition mask and a manufacturing method for forming a display panel pattern using the same and an electronic device.

### 2. Description of the Related Art

Wearable devices in which a focus is formed at a distance close to user's eyes have been developed in the form of glasses or a helmet. For example, the wearable device may be a head mounted display (“HMD”) device or augmented reality (“AR”) glasses. The wearable device provides an AR screen or a virtual reality (“VR”) screen to a user.

A display specification of at least 2000 pixels per inch (ppi) may be desired in the wearable devices such as the HMD device or the AR glasses so that a user may use it for a long time without dizziness. To this end, organic light-emitting diode on silicon (“OLEDoS”) technology that is a high-resolution relatively small organic light-emitting display device is emerging. The OLEDoS is technology for disposing an organic light-emitting diode (“OLED”) on a semiconductor wafer substrate on which a complementary metal oxide semiconductor (“CMOS”) is disposed.

### SUMMARY

Features of the disclosure provide a deposition mask capable of reducing stress caused by a difference in physical properties between a substrate of the mask and a thin film stacked on the substrate, and reducing warpage, which is a bending characteristic of the mask, and a manufacturing method for forming a display panel pattern using the same.

In an embodiment of the disclosure, a deposition mask includes: a substrate including a plurality of cell regions, a mask lip region partitioning the plurality of cell regions, and an outer frame region disposed at an outer edge of the plurality of cell regions; a mask membrane defined by an inorganic film pattern which is a portion of an inorganic film or disposed on the substrate and disposed to correspond to the plurality of cell regions; and a dummy inorganic film pattern which is a remaining portion of the inorganic film except for the inorganic film pattern, where the dummy inorganic film pattern includes a first dummy inorganic film pattern disposed in the mask lip region, and a second dummy inorganic film pattern disposed in a portion of the outer frame region, and a lip opening exposing a surface of the substrate in the mask lip region is defined in the first dummy inorganic film pattern.

In an embodiment, the lip opening may be disposed to surround the plurality of cell regions, and be disposed in a straight line along a first direction in which the mask lip region extends or a second direction perpendicular to the first direction.

In an embodiment, the lip opening may include: a first lip opening extending in the first direction; and a second lip opening extending in the second direction so as to intersect the first lip opening.

In an embodiment, in a region where the first lip opening and the second lip opening intersect, the first lip opening is segmented, and in a region where the first lip opening and the second lip opening intersect, the second lip opening may be continuous.

In an embodiment, in a region where the first lip opening and the second lip opening intersect, the second lip opening is segmented, and in a region where the first lip opening and the second lip opening intersect, the first lip opening may be continuous.

In an embodiment, in a region where the first lip opening and the second lip opening intersect, each of the first lip opening and the second lip opening may be segmented.

In an embodiment, the second dummy inorganic film pattern may define: a first outer opening exposing the surface of the substrate in a first outer frame region of the outer frame region next (adjacent) to one side of the substrate; and a second outer opening exposing the surface of the substrate in a second outer frame region of the outer frame region next (adjacent) to an opposite side of the substrate, where the first outer opening and the second outer opening may have a symmetrical shape with respect to a center of the substrate.

In an embodiment, the second dummy inorganic film pattern may define: a third outer opening exposing the surface of the substrate in a first edge region of the substrate disposed in a first diagonal direction between the first direction and the second direction from a center of the substrate; a fourth outer opening exposing the surface of the substrate in a second edge region of the substrate disposed in a second diagonal direction perpendicular to the first diagonal direction from the center of the substrate; a fifth outer opening exposing the surface of the substrate in a third edge region of the substrate disposed in a third diagonal direction opposite to the first diagonal direction from the center of the substrate; and a sixth outer opening exposing the surface of the substrate in a fourth edge region of the substrate disposed in a fourth diagonal direction opposite to the second diagonal direction from the center of the substrate, where the third outer opening and the fifth outer opening may have a symmetrical shape with respect to the center of the substrate, and the fourth outer opening and the sixth outer opening have a symmetrical shape with respect to the center of the substrate.

In an embodiment, the inorganic film pattern disposed in each of cell regions next to each other among the plurality of cell regions may be segmented by the lip opening.

In an embodiment, a trench may be defined in the substrate and have a predetermined depth in the lip opening.

In an embodiment, the inorganic film may be a single film.

In an embodiment, the inorganic film may include a first inorganic film deposited on the substrate, and a second inorganic film deposited on the first inorganic film.

In an embodiment of the disclosure, a deposition mask includes: a substrate including a plurality of cell regions, a mask lip region partitioning the plurality of cell regions, and an outer frame region disposed at an outer edge of the plurality of cell regions; a mask membrane defined by an inorganic film pattern which is a portion of an inorganic film including a first inorganic film disposed on the substrate and a second inorganic film on the first inorganic film, and disposed to correspond to the plurality of cell regions; and a dummy inorganic film pattern which is a remaining portion of the inorganic film except for the inorganic film pattern, where the dummy inorganic film pattern includes a first dummy inorganic film pattern disposed in the mask lip region, and a second dummy inorganic film pattern disposed in a portion of the outer frame region, and a lip opening exposing the surface of the first inorganic film is defined in the first dummy inorganic film pattern.

In an embodiment, the lip opening may be disposed to surround the plurality of cell regions, and be disposed in a straight line along a first direction in which the mask lip region extends or a second direction perpendicular to the first direction.

In an embodiment, the lip opening may include: a first lip opening extending in the first direction; and a second lip opening extending in the second direction so as to intersect the first lip opening.

In an embodiment, in a region where the first lip opening and the second lip opening intersect, the first lip opening is segmented, and in a region where the first lip opening and the second lip opening intersect, the second lip opening may be continuous.

In an embodiment, in a region where the first lip opening and the second lip opening intersect, the second lip opening is segmented, and in a region where the first lip opening and the second lip opening intersect, the first lip opening may be continuous.

In an embodiment, in a region where the first lip opening and the second lip opening intersect, each of the first lip opening and the second lip opening may be segmented.

In an embodiment, a thickness of the first inorganic film exposed through the lip opening may be equal to a thickness of the first inorganic film disposed in the plurality of cell regions.

In an embodiment, a thickness of the first inorganic film exposed through the lip opening may be less than a thickness of the first inorganic film disposed in the plurality of cell regions.

In an embodiment of the disclosure, a manufacturing method for forming a display panel pattern using a deposition mask includes: allowing a material vaporized from a deposition source to pass through the deposition mask and be deposited on a display panel, where the deposition mask includes: a substrate including a plurality of cell regions, a mask lip region partitioning the plurality of cell regions, and an outer frame region disposed at an outer edge of the plurality of cell regions; a mask membrane defined by an inorganic film pattern which is a portion of an inorganic film formed on the substrate and disposed to correspond to the plurality of cell regions; and a dummy inorganic film pattern which is a remaining portion of the inorganic film except for the inorganic film pattern, where the dummy inorganic film pattern includes a first dummy inorganic film pattern disposed in the mask lip region, and a second dummy inorganic film pattern disposed in a portion of the outer frame region, and a lip opening exposing a surface of the substrate in the mask lip region is defined in the first dummy inorganic film pattern.

In an embodiment, the lip opening may be disposed to surround the plurality of cell regions, and be disposed in a straight line along a first direction in which the mask lip region extends or a second direction perpendicular to the first direction.

In an embodiment, the lip opening may include: a first lip opening extending in the first direction; and a second lip opening extending in the second direction so as to intersect the first lip opening.

In an embodiment, in a region where the first lip opening and the second lip opening intersect, the first lip opening is segmented, and in a region where the first lip opening and the second lip opening intersect, the second lip opening may be continuous.

In an embodiment, in a region where the first lip opening and the second lip opening intersect, the second lip opening is segmented, and in a region where the first lip opening and the second lip opening intersect, the first lip opening may be continuous.

However, features of the disclosure are not restricted to the one set forth herein. The above and other features of the disclosure will become more apparent to one of ordinary skill in the art to which the disclosure pertains by referencing the detailed description of the disclosure given below.

In the deposition mask and the manufacturing method for forming a display panel pattern using the same in embodiments, stress caused by a difference in physical properties between the substrate of the mask and the thin film stacked on the substrate may be reduced, and warpage, which is a bending characteristic of the mask, may be reduced.

In the deposition mask and the manufacturing method for forming a display panel pattern using the same in embodiments, it is possible to reduce issues of damage to the mask during the deposition process using the mask and the mask cleaning process by reducing the warpage, which is a bending characteristic of the mask.

However, effects by the embodiments of the disclosure are not limited to those exemplified above and various other effects are incorporated herein.

### BRIEF DESCRIPTION OF THE DRAWINGS

The above and other advantages and features of the disclosure will become more apparent by describing in detail embodiments thereof with reference to the attached drawings, in which.

FIG. 1 is an exploded perspective view showing a display device according to one embodiment;

FIG. 2 is a block diagram illustrating a display device according to one embodiment;

FIG. 3 is an equivalent circuit diagram of a first sub-pixel according to one embodiment;

FIG. 4 is a layout diagram illustrating an example of a display panel according to one embodiment;

FIGS. 5 and 6 are layout diagrams illustrating embodiments of the display area of FIG. 4;

FIG. 7 is a cross-sectional view illustrating an example of a display panel taken along line Il-Il′ of FIG. 5;

FIG. 8 is a perspective view illustrating a head mounted display according to one embodiment;

FIG. 9 is an exploded perspective view illustrating an example of the head mounted display of FIG. 8;

FIG. 10 is a perspective view illustrating a head mounted display according to one embodiment;

FIG. 11 is a perspective view of an embodiment of a mask;

FIG. 12 is a schematic plan view of an embodiment of a mask;

FIG. 13 is a schematic plan view of a comparative example of a mask;

FIG. 14 is a cross-sectional view of the comparative example of a mask in taken along line A-A′ shown in FIG. 13;

FIG. 15 is a conceptual diagram illustrating the warpage characteristic of the mask shown in FIG. 13;

FIG. 16 is a plan view of an embodiment of a mask;

FIG. 17 is a cross-sectional view of the mask of an embodiment taken along line A-A′ shown in FIG. 16;

FIG. 18 is a conceptual diagram illustrating the warpage characteristic of the mask shown in FIG. 16;

FIGS. 19 to 23 are plan views of a mask illustrating the shapes of a lip opening according to various embodiments;

FIG. 24 is a schematic cross-sectional view of an embodiment of a mask further including a trench;

FIGS. 25 to 28 are schematic cross-sectional views of a mask according to various embodiments in which an inorganic film has a multilayer structure; and

FIG. 29 is a conceptual diagram illustrating a warp characteristic of a mask.

FIG. 30 is a block diagram of an electronic device according to one embodiment.

FIGS. 31, 32 and 33 are schematic diagrams of electronic devices according to various embodiments.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is also referred to as being “on” another layer or substrate, it may be directly on the other layer or substrate, or intervening layers may also be present. The same reference numbers indicate the same components throughout the specification. In the attached drawing figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the disclosure may be combined partially or totally. As will be clearly appreciated by those skilled in the art, technically various interactions and operations are possible. Various embodiments may be practiced individually or in combination.

Hereinafter, predetermined embodiments will be described with reference to the accompanying drawings.

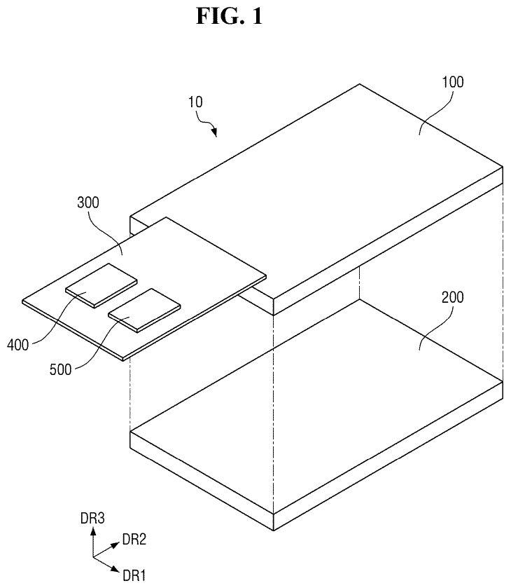

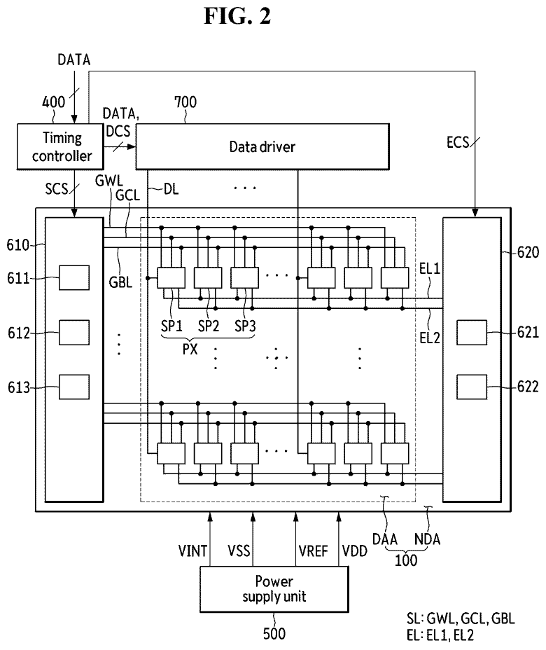

FIG. 1 is an exploded perspective view showing a display device according to one embodiment. FIG. 2 is a block diagram illustrating a display device according to one embodiment.

Referring to FIGS. 1 and 2, a display device 10 according to one embodiment is a device displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to one embodiment may be applied as a display unit of a television, a laptop, a monitor, a billboard, or an Internet-of-Things (IoT) terminal. Alternatively, the display device 10 according to one embodiment may be applied to a smart watch, a watch phone, a head mounted display (HMD) for implementing virtual reality and augmented reality, and the like.

The display device 10 according to one embodiment includes a display panel 100, a heat dissipation layer 200, a circuit board 300, a timing controller 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

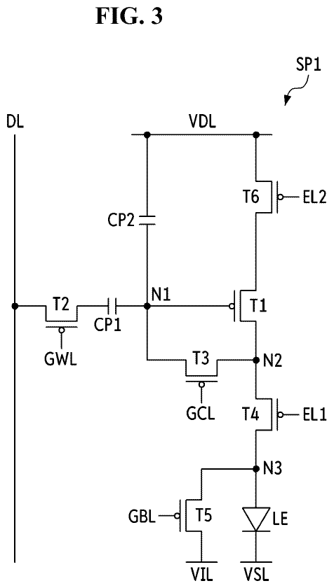

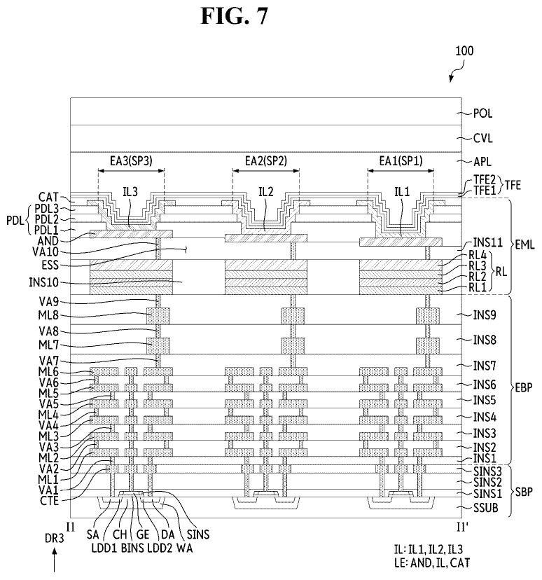

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The non-display area NDA includes a scan driver 610, an emission driver 620, and a data driver 700.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed of CMOS.

Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS.

The data driver 700 may receive digital video data DATA and a data timing control signal DCS from the timing controller 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 130 may include a metal layer such as graphite, silver (Ag), copper (Cu), or aluminum (Al) having high thermal conductivity.

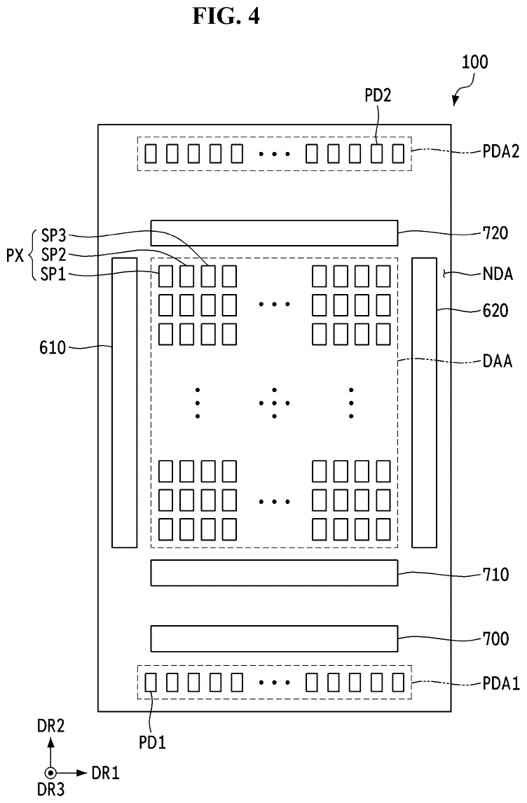

The circuit board 300 may be electrically connected to a plurality of first pads PD1 (see FIG. 4) of a first pad portion PDA1 (see FIG. 4) of the display panel 100 by using a conductive adhesive member such as an anisotropic conductive layer. The circuit board 300 may be a flexible printed circuit board with a flexible material, or a flexible layer. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing controller 400 may receive digital video data DATA and timing signals inputted from the outside. The timing controller 400 may generate the scan timing control signal SCS, the emission timing control signal ECS, and the data timing control signal DCS for controlling the display panel 100 in response to the timing signals. The timing controller 400 may output the scan timing control signal SCS to the scan driver 610, and output the emission timing control signal ECS to the emission driver 620. The timing controller 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing controller 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, similarly to the scan driver 610, the emission driver 620, and the data driver 700, each of the timing controller 400 and the power supply circuit 500 may be disposed in the non-display area NDA of the display panel 100. In this case, the timing controller 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS. Each of the timing controller 400 and the power supply circuit 500 may be disposed between the data driver 700 and the first pad portion PDA1 (see FIG. 4).

FIG. 3 is an equivalent circuit diagram of a first sub-pixel according to one embodiment.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a driving current Ids flowing through the channel of the first transistor T1. The emission amount of the light-emitting element LE may be proportional to the driving current Ids. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (Ids, hereinafter referred to as “driving current”) flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the write control signal of the write control line GCL to connect the first node N1 to the second node N2. For this reason, since the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL.

Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one embodiment.

Referring to FIG. 4, the display area DAA of the display panel 100 according to one embodiment includes the plurality of pixels PX arranged in a matrix form. The non-display area NDA of the display panel 100 according to one embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. That is, the first pad portion PDA1 is the display area DAA.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally.

The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, the second distribution circuit 720 may be disposed on the upper side of the display area DAA.

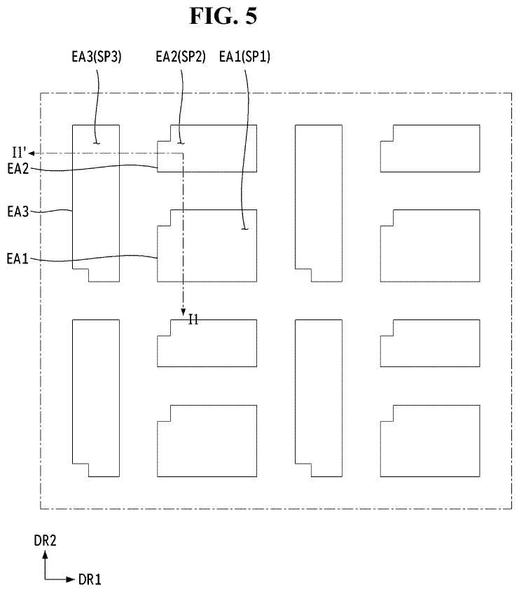

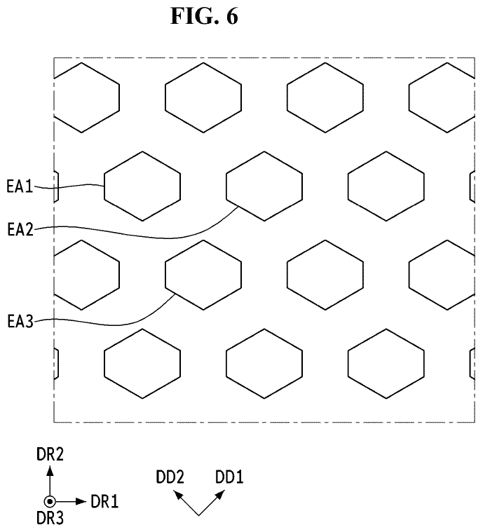

FIGS. 5 and 6 are layout diagrams illustrating embodiments of the display area of FIG. 4.

Referring to FIGS. 5 and 6, each of the pixels PX includes the first emission area EAT that is an emission area of the first sub-pixel SP1, the second emission area EA2 that is an emission area of the second sub-pixel SP2, and the third emission area EA3 that is an emission area of the third sub-pixel SP3.

Each of the first emission area EAT, the second emission area EA2, and the third emission area EA3 may have a polygonal, circular, elliptical, or atypical shape in plan view.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EAT in the second direction DR2 may be greater than the maximum length of the second emission area EA2 in the second direction DR2.

The first emission area EAT, the second emission area EA2, and the third emission area EA3 may have, in plan view, a hexagonal shape formed of six straight lines as shown in FIGS. 5 and 6, but the present disclosure is not limited thereto. The first emission area EAT, the second emission area EA2, and the third emission area EA3 may have a polygonal shape other than a hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EAT, the area of the second emission area EA2, and the area of the third emission area EA3 may be different.

Alternatively, as shown in FIG. 6, the first emission area EA1 and the second emission area EA2 may be adjacent to each other in the first direction DRT, but the second emission area EA2 and the third emission area EA3 may be adjacent to each other in a first diagonal direction DD1, and the first emission area EAT and the third emission area EA3 may be adjacent to each other in a second diagonal direction DD2. The first diagonal direction DD1 may be a direction between the first direction DRT and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the second light may be light of a green wavelength band, and the third light may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is exemplified in FIGS. 5 and 6 that each of the plurality of pixels PX includes three emission areas EAT, EA2, and EA3, but the present disclosure is not limited thereto.

That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be disposed in a stripe structure in which the emission areas are arranged in the first direction DR1, a PenTile® structure in which the emission areas are arranged in a diamond shape, or a hexagonal structure in which the emission areas having, in plan view, a hexagonal shape are arranged as shown in FIG. 6.

FIG. 7 is a cross-sectional view illustrating an example of a display panel taken along line Il-Il′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity.

Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating layer SINS1 may be disposed on the semiconductor substrate SSUB. The first semiconductor insulating layer SINS1 may be formed of silicon carbonitride (SiCN) or a silicon oxide (SiOx)-based inorganic layer, but the present disclosure is not limited thereto.

A second semiconductor insulating layer SINS2 may be disposed on the first semiconductor insulating layer SINS1. The second semiconductor insulating layer SINS2 may be formed of a silicon oxide (SiOx)-based inorganic layer, but the present disclosure is not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through a hole penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the plurality of contact terminals CTE. The top surface of each of the plurality of contact terminals CTE may be exposed without being covered by the third semiconductor insulating layer SINS3. The third semiconductor insulating layer SINS3 may be formed of a silicon oxide (SiOx)-based inorganic layer, but the present disclosure is not limited thereto.

The semiconductor substrate SSUB may be replaced with a glass substrate or a polymer resin substrate such as polyimide. In this case, thin layer transistors may be disposed on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VAT to VA9, and a plurality of insulating layers INS1 to INS9. In addition, the light-emitting element backplane EBP includes a plurality of insulating layers INS1 to INS9 disposed between the first to eighth conductive layers ML1 to ML8.

The first to eighth conductive layers ML1 to ML8 serve to connect the plurality of contact terminals CTE exposed from the semiconductor backplane SBP to thereby implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating layer INS1 may be disposed on the semiconductor backplane SBP. Each of the first vias VA1 may penetrate the first insulating layer INS1 and be connected to the contact terminal CTE exposed from the semiconductor backplane SBP. Each of the first conductive layers ML1 may be disposed on the first insulating layer INS1 and may be connected to the first via VA1.

The second insulating layer INS2 may be disposed on the first insulating layer INS1 and the first conductive layers ML1. Each of the second vias VA2 may penetrate the second insulating layer INS2 and be connected to the exposed first conductive layer ML1. Each of the second conductive layers ML2 may be disposed on the second insulating layer INS2 and may be connected to the second via VA2.

The third insulating layer INS3 may be disposed on the second insulating layer INS2 and the second conductive layers ML2. Each of the third vias VA3 may penetrate the third insulating layer INS3 and be connected to the exposed second conductive layer ML2. Each of the third conductive layers ML3 may be disposed on the third insulating layer INS3 and may be connected to the third via VA3.

A fourth insulating layer INS4 may be disposed on the third insulating layer INS3 and the third conductive layers ML3. Each of the fourth vias VA4 may penetrate the fourth insulating layer INS4 and be connected to the exposed third conductive layer ML3. Each of the fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of the fifth vias VA5 may penetrate the fifth insulating layer INS5 and be connected to the exposed fourth conductive layer ML4. Each of the fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of the sixth vias VA6 may penetrate the sixth insulating layer INS6 and be connected to the exposed fifth conductive layer ML5. Each of the sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of the seventh vias VA7 may penetrate the seventh insulating layer INS7 and be connected to the exposed sixth conductive layer ML6. Each of the seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of the eighth vias VA8 may penetrate the eighth insulating layer INS8 and be connected to the exposed seventh conductive layer ML7. Each of the eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to ILD8 may be formed of a silicon oxide (SiOx)-based inorganic layer, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VAT, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VAT, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating layer INS9 may be disposed on the eighth insulating layer INS8 and the eighth conductive layer ML8. The ninth insulating layer INS9 may be formed of a silicon oxide (SiOx)-based inorganic layer, but the present disclosure is not limited thereto.

Each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

The display element layer EML may be disposed on the light-emitting element backplane EBP. The display element layer EML may include light-emitting elements LE each including a reflective electrode layer RL, tenth and eleventh insulating layers INS10 and INS11, a tenth via VA10, the first electrode AND, alight-emitting stack IL, and a second electrode CAT, and a pixel defining layer PDL and, a plurality of trenches TRC.

The reflective electrode layer RL may be disposed on the ninth insulating layer INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be disposed on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating layer INS10 may be disposed on the ninth insulating layer INS9. The tenth insulating layer INS10 may be disposed between the reflective electrode layers RL adjacent to each other in a horizontal direction. The tenth insulating layer INS10 may be formed of a silicon oxide (SiOx)-based inorganic layer, but the present disclosure is not limited thereto.

The eleventh insulating layer INS11 may be disposed on the tenth insulating layer INS10 and the reflective electrode layer RL. The eleventh insulating layer INS11 may be formed of a silicon oxide (SiOx)-based inorganic layer, but the present disclosure is not limited thereto. The tenth insulating layer INS10 and the eleventh insulating layer INS11 may be an optical auxiliary layer through which light reflected by the reflective electrode layer RL passes, among light emitted from the light-emitting elements LE.

In order to match the resonance distance of the light emitted from the light-emitting elements LE in at least one of the first sub-pixel SP1, the second sub-pixel SP2, or the third sub-pixel SP3, the tenth insulating layer INS10 or the eleventh insulating layer INS11 may not be disposed under the first electrode AND. For example, the first electrode AND of the first sub-pixel SP1 may be directly disposed on the reflective electrode layer RL. The eleventh insulating layer INS11 may be disposed under the first electrode AND of the second sub-pixel SP2. The tenth insulating layer INS10 and the eleventh insulating layer INST1 may be disposed under the first electrode AND of the third sub-pixel SP3.

In summary, the distance between the first electrode AND and the reflective electrode layer RL may be different in the first sub-pixel SP1, the second sub-pixel SP2, and the third sub-pixel SP3. That is, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating layer INS10 and the eleventh insulating layer INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The present disclosure is not limited to the above examples.

In addition, although the tenth insulating layer INS10 and the eleventh insulating layer INS11 are illustrated in the present disclosure, a twelfth insulating layer disposed under the first electrode AND of the first sub-pixel SP1 may be added. In this case, the eleventh insulating layer INS11 and the twelfth insulating layer may be disposed under the first electrode AND of the second sub-pixel SP2, and the tenth insulating layer INS10, the eleventh insulating layer INS11, and the twelfth insulating layer may be disposed under the first electrode AND of the third sub-pixel SP3.

Each of the tenth vias VA10 may penetrate the tenth insulating layer INS10 and/or the eleventh insulating layer INS11 in the second sub-pixel SP2 and the third sub-pixel SP3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be less than the thickness of the tenth via VA10 in the third sub-pixel SP3.

The first electrode AND of each of the light-emitting elements LE may be disposed on the tenth insulating layer INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VAT to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining layer PDL may be disposed on a part of the first electrode AND of each of the light-emitting elements LE. The pixel defining layer PDL may cover the edge of the first electrode AND of each of the light-emitting elements LE. The pixel defining layer PDL may serve to partition the first emission areas EAT, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining layer PDL may include first to third pixel defining layers PDL1, PDL2, and PDL3. The first pixel defining layer PDL1 may be disposed on the edge of the first electrode AND of each of the light-emitting elements LE, the second pixel defining layer PDL2 may be disposed on the first pixel defining layer PDL1, and the third pixel defining layer PDL3 may be disposed on the second pixel defining layer PDL2. The first pixel defining layer PDL1, the second pixel defining layer PDL2, and the third pixel defining layer PDL3 may be formed of a silicon oxide (SiOx)-based inorganic layer, but the present disclosure is not limited thereto. The first pixel defining layer PDL1, the second pixel defining layer PDL2, and the third pixel defining layer PDL3 may each have a thickness of about 500 Å.

When the first pixel defining layer PDL1, the second pixel defining layer PDL2, and the third pixel defining layer PDL3 are formed as one pixel defining layer, the height of the one pixel defining layer increases, so that a first encapsulation inorganic layer TFE1 may be cut off due to step coverage. Step coverage refers to the ratio of the degree of thin layer coated on an inclined portion to the degree of thin layer coated on a flat portion. The lower the step coverage, the more likely it is that the thin layer will be cut off at inclined portions.

Therefore, in order to reduce or prevent the likelihood of the first encapsulation inorganic layer TFE1 being cut off due to the step coverage, the first pixel defining layer PDL1, the second pixel defining layer PDL2, and the third pixel defining layer PDL3 may have a cross-sectional structure having a stepped portion. For example, the width of the first pixel defining layer PDL1 may be greater than the width of the second pixel defining layer PDL2 and the width of the third pixel defining layer PDL3, and the width of the second pixel defining layer PDL2 may be greater than the width of the third pixel defining layer PDL3. The width of the first pixel defining layer PDL1 refers to the horizontal length of the first pixel defining layer PDL1 defined in the first direction DR1 and the second direction DR2.

Each of the plurality of trenches TRC may penetrate the first pixel defining layer PDL1, the second pixel defining layer PDL2, and the third pixel defining layer PDL3. In addition, each of the plurality of trenches TRC may penetrate the eleventh insulating layer INS11. A portion of the tenth insulating layer INS10 may be recessed in each of the plurality of trenches TRC.

At least one trench TRC may be disposed between adjacent sub-pixels SP1, SP2, SP3. Although FIG. 7 illustrates an example in which two trenches TRC are disposed between adjacent sub-pixels SP1, SP2, SP3, the embodiments of the present disclosure are not limited thereto.

The light-emitting stack IL may include a plurality of intermediate layers. In FIG. 7, the light-emitting stack IL is illustrated as having a three-tandem structure including a first stack layer IL1, a second stack layer IL2, and a third stack layer IL3. However, the embodiments of the present disclosure are not limited thereto. For example, the light-emitting stack IL may have a two-tandem structure including two intermediate layers.

In a three-tandem structure, the light-emitting stack IL may have a tandem structure including a plurality of stack layers IL1, IL2, IL3 that emit different colors of light. For example, the light-emitting stack IL may include a first stack layer IL1 that emits light of a first color, a second stack layer IL2 that emits light of a third color, and a third stack layer IL3 that emits light of a second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked.

The second stack layer IL2 may have a structure in which a second hole transport layer, a second organic light-emitting layer that emits light of the third color, and a second electron transport layer are sequentially stacked.

The third stack layer IL3 may have a structure in which a third hole transport layer, a third organic light-emitting layer that emits light of the second color, and a third electron transport layer are sequentially stacked.

A first charge generation layer may be disposed between the first stack layer IL1 and the second stack layer IL2 to supply charges to the second stack layer IL2 and electrons to the first stack layer IL1. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer may be disposed between the second stack layer IL2 and the third stack layer IL3 to supply charges to the third stack layer IL3 and electrons to the second stack layer IL2. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining layer PDL, and may be disposed at the bottom surface of each trench TRC. Due to the trench TRC, the first stack layer IL1 may be cut off between adjacent sub-pixels SP1, SP2, SP3. The second stack layer IL2 may be disposed on the first stack layer IL1. Due to the trench TRC, the second stack layer IL2 may also be cut off between adjacent sub-pixels SP1, SP2, SP3. A cavity or empty space may be provided between the first stack layer IL1 and the second stack layer IL2. The third stack layer IL3 may be disposed on the second stack layer IL2. The third stack layer IL3 is not cut off by the trench TRC and may be disposed so as to cover the second stack layer IL2 in each trench TRC. That is, in a three-tandem structure, each of the plurality of trenches TRC may serve as a structure for cutting off the first and second stack layers IL1, IL2 of the display element layer EML, the first charge generation layer, and the second charge generation layer between adjacent sub-pixels SP1, SP2, SP3. In a two-tandem structure, each of the plurality of trenches TRC may serve as a structure for cutting off the charge generation layer and the lower intermediate layer, which are disposed between the lower and upper intermediate layers.

In order to reliably cutting of the first and second stack layers IL1, IL2 of the display element layer EML between adjacent sub-pixels SP1, SP2, SP3, the height of each of the plurality of trenches TRC may be greater than the height of the pixel defining layer PDL. The height of each of the plurality of trenches TRC refers to the length of each trench TRC in the third direction DR3. The height of the pixel defining layer PDL refers to the length of the pixel defining layer PDL in the third direction (DR3). To cutting off the first to third stack layers IL1, IL2, IL3 of the display element layer EML between adjacent sub-pixels SP1, SP2, SP3, a structure other than the trench TRC may be provided. For example, instead of the trench TRC, a reverse-tapered partition wall may be disposed on the pixel defining layer PDL.

The number of stack layers IL1, IL2, IL3 that emit different colors of light is not limited to that shown in FIG. 7. For example, the light-emitting stack IL may include two intermediate layers. In this case, one of the two intermediate layers may be substantially the same as the first stack layer IL1, and the other may include a second hole transport layer, a second organic light-emitting layer, a third organic light-emitting layer, and a second electron transport layer. In this case, a charge generation layer may be disposed between the two intermediate layers to supply electrons to one of the intermediate layers and charges to the other.

In addition, although FIG. 7 illustrates an example in which the first to third stack layers IL1, IL2, IL3 are all disposed in the first emission area EA1, the second emission area EA2, and the third emission area EA3, the embodiments of the present disclosure are not limited thereto. For example, the first stack layer IL1 may be disposed in the first emission area EA1 and may not be disposed in the second emission area EA2 and the third emission area EA3. Likewise, the second stack layer IL2 may be disposed in the second emission area EA2 and may not be disposed in the first emission area EA1 and the third emission area EA3. Similarly, the third stack layer IL3 may be disposed in the third emission area EA3 and may not be disposed in the first emission area EA1 and the second emission area EA2. In this case, the first to third color filters CF1, CF2, CF3 of the optical layer OPL may be omitted.

The second electrode CAT may be disposed on the third stack layer IL3. The second electrode CAT may be formed of a transparent conductive material (TCO) such as ITO or IZO that can transmit light or a semi-transmissive metal material such as magnesium (Mg), silver (Ag), or an alloy of Mg and Ag. When the second electrode CAT is formed of a semi-transmissive metal material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic layer TFE1 and TFE2 to reduce or prevent oxygen or moisture from permeating into the display element layer EML. For example, the encapsulation layer TFE may include the first encapsulation inorganic layer TFE1, and a second encapsulation inorganic layer TFE2.

The first encapsulation inorganic layer TFE1 may be disposed on the second electrode CAT. The first encapsulation inorganic layer TFE1 may be formed as a multilayer in which one or more inorganic layers selected from silicon nitride (SiNx), silicon oxy nitride (SiON), and silicon oxide (SiOx) are alternately stacked. The first encapsulation inorganic layer TFE1 may be formed by a chemical evaporation deposition (CVD) process.

The second encapsulation inorganic layer TFE2 may be disposed on the first encapsulation inorganic layer TFE1. The second encapsulation inorganic layer TFE2 may be formed of titanium oxide (TiOx) or aluminum oxide layer (AlOx), but the present disclosure is not limited thereto. The second encapsulation inorganic layer TFE2 may be formed by an atomic layer deposition (ALD) process. The thickness of the second encapsulation inorganic layer TFE2 may be less than the thickness of the first encapsulation inorganic layer TFE1.

An organic layer APL may be a layer for increasing the interfacial adhesion between the encapsulation layer TFE and the optical layer OPL. The organic layer APL may be an organic layer such as acrylic resin, epoxy resin, phenolic resin, polyamide resin, or polyimide resin.

The optical layer OPL includes aplurality of color filters CFT, CF2, CF3, aplurality of lenses LNS, and a filling layer FIL. The plurality of color filters CFT, CF2, CF3 may include first to third color filters CFT, CF2, CF3. The first to third color filters CFT, CF2, CF3 may be disposed on an organic layer APL.

The first color filter CF1 may overlap with the first emission area EA1 of the first sub-pixel SP1. The first color filter CF1 may transmit light of a first color, namely light in the blue wavelength range. The blue wavelength range may be approximately from 370 nm to 460 nm. Therefore, the first color filter CF1 may transmit light of the first color among the light emitted from the first emission area EAT.

The second color filter CF2 may overlap with the second emission area EA2 of the second sub-pixel SP2. The second color filter CF2 may transmit light of a second color, namely light in the green wavelength range. The green wavelength range may be approximately from 480 nm to 560 nm. Therefore, the second color filter CF2 may transmit light of the second color among the light emitted from the second emission area EA2.

The third color filter CF3 may overlap with the third emission area EA3 of the third sub-pixel SP3. The third color filter CF3 may transmit light of a third color, namely light in the red wavelength range. The red wavelength range may be approximately from 600 nm to 750 nm. Therefore, the third color filter CF3 may transmit light of the third color among the light emitted from the third emission area EA3.

Each of the plurality of lenses LNS may be disposed on each of the first color filter CF1, the second color filter CF2, and the third color filter CF3. Each of the plurality of lenses LNS may serve as a structure for increasing the proportion of light directed toward the front side of the display device 10. Each of the plurality of lenses LNS may have a convex cross-sectional shape in the upward direction.

The filling layer FIL may be disposed on the plurality of lenses LNS. The filling layer FIL may have a predetermined refractive index so that light can travel in the third direction DR3 at the interface between the plurality of lenses LNS and the filling layer FIL. In addition, the filling layer FIL may serve as a planarization layer. The filling layer FIL may be an organic layer such as an acryl resin, epoxy resin, phenolic resin, polyamide resin, or polyimide resin.

The cover layer CVL may be disposed on the filling layer FIL. The cover layer CVL may be a glass substrate or a polymer resin such as resin. When the cover layer CVL is a glass substrate, it may be attached on the filling layer FIL. In this case, the filling layer FIL may serve as an adhesive layer for bonding the cover layer CVL. When the cover layer CVL is a glass substrate, it may function as an encapsulation substrate. When the cover layer CVL is a polymer resin such as resin, it may be directly applied on the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation layer. For example, the phase retardation layer may be λ/4 plate (quarter-wave plate), but the present disclosure is not limited thereto. However, if the first to third color filters CF1, CF2, CF3 sufficiently improve visibility by reducing external light reflection, a polarizer may be omitted.

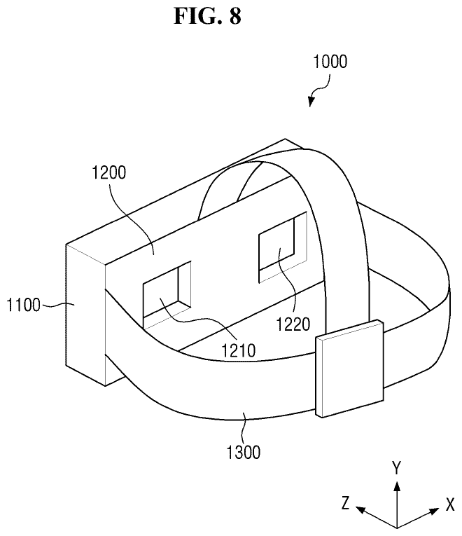

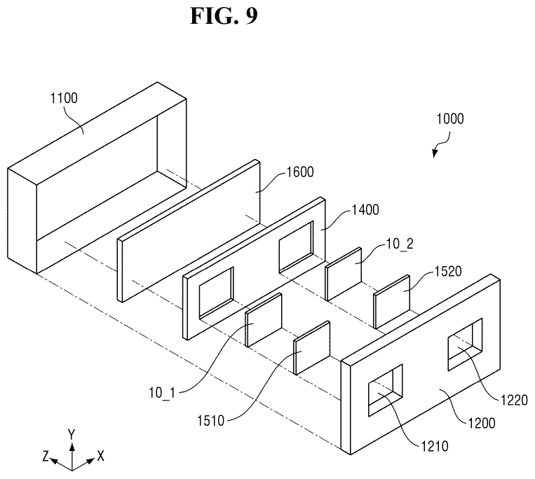

FIG. 8 is a perspective view illustrating a head mounted display according to one embodiment. FIG. 9 is an exploded perspective view illustrating an example of the head mounted display of FIG. 8.

Referring to FIGS. 8 and 9, a head mounted display 1000 according to one embodiment includes a first display device 10_1, a second display device 102, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 101, the second display device 10_2, and the control circuit board 1600.

The control circuit board 1600 may be disposed between the middle frame 1400 and the display device housing 1100. The control circuit board 1600 may be connected to the first display device 10_1 and the second display device 102 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 101, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 102, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

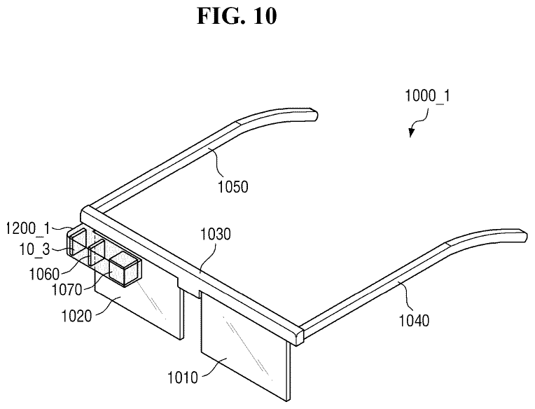

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display according to one embodiment.

Referring to FIG. 10, ahead mounted display 1000_1 according to one embodiment may be an eyeglasses-type display device in which a display device housing 1200_1 is implemented in a lightweight and compact manner. The head mounted display 1000_1 according to one embodiment may include a display device 103, a left eye lens 1010, a right eye lens 1020, a support frame 1030, temples 1040 and 1050, an optical member 1600, an optical path changing member 1070, and the display device housing 1200_1.

The display device housing 1200_1 may include the display device 103, the optical member 1600, and the optical path changing member 1070. The image displayed on the display device 10_3 may be magnified by the optical member 1600, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. Alternatively, the display device housing 1200_1 may be disposed at both the left and right ends of the support frame 1030, and in this case, the user may view the image displayed on the display device 10_3 through both the left and right eyes.

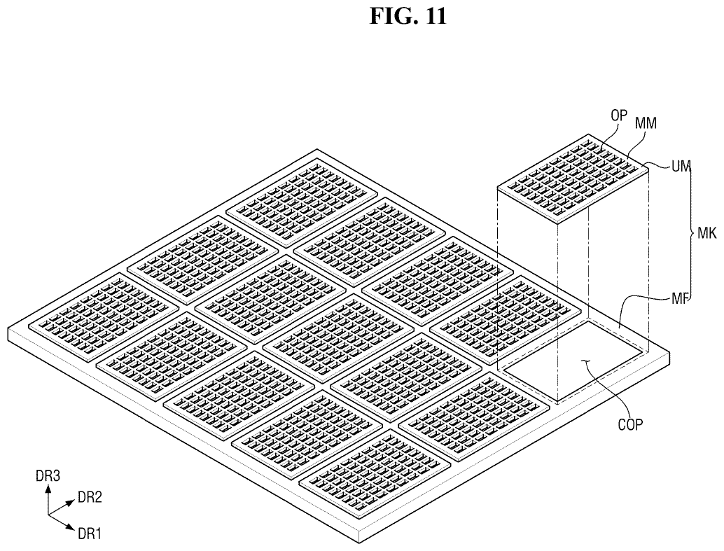

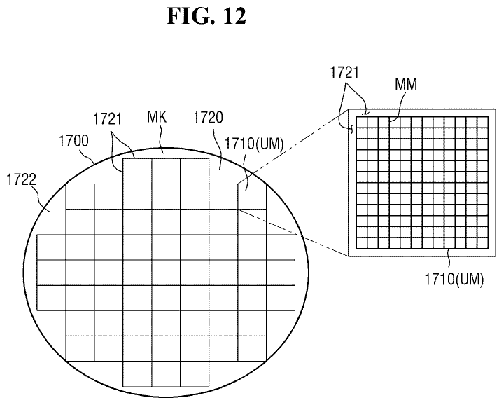

FIG. 11 is a perspective view of an embodiment of a mask. FIG. 12 is a schematic plan view of an embodiment of a mask. FIG. 11 shows a perspective view of a state in which one unit mask UM is separated from a plurality of unit masks. The mask in an embodiment shown in FIGS. 11 and 12 may be used in the process of depositing at least a portion of the light-emitting stack IL described with reference to FIG. 7. In an embodiment, the light-emitting stack IL may emit a different color in each of the sub-pixels SP1, SP2, and SP3, for example.

A manufacturing method for forming a pattern of the display panel 100 using a mask (e.g., deposition mask) MK in an embodiment may include a step of allowing a material vaporized from a deposition source to pass through the mask MK and be deposited on the display panel 100. Here, a layer deposited on the display panel 100 may include at least some layers of the light-emitting stack IL described with reference to FIG. 7.

Referring to FIGS. 11 and 12, the mask MK in an embodiment may be a shadow mask in which a mask membrane MM is disposed on a silicon substrate 1700. The mask MK in an embodiment may be also referred to as “silicon mask.”

In an embodiment, the mask MK may include the silicon substrate 1700, and the mask membrane MM may be disposed on the silicon substrate 1700. The mask membrane MM may be disposed in cell regions 1710 arranged in a matrix form, and each cell region 1710 may be surrounded by a mask lip region 1721. The mask lip region 1721 may have a portion of the silicon substrate disposed therein, and may serve to support the mask membrane MM.

The mask membrane MM may be a part of the unit mask UM disposed in each of the plurality of cell regions 1710.

The silicon substrate 1700 may include the plurality of cell regions 1710 and a mask frame region 1720 excluding the plurality of cell regions 1710. The mask frame region 1720 may include the mask lip region 1721 surrounding each cell region 1710, and an outer frame region 1722 disposed at the outermost edge of the silicon substrate 1700. A mask frame MF may be disposed in the mask frame region 1720, and the mask frame MF may include a mask lip surrounding the cell region 1710.

The mask lip region 1721 may be a region that partitions the plurality of cell regions 1710. In an embodiment, the plurality of cell regions 1710 may be arranged in a matrix form, and the mask lip disposed in the mask lip region 1721 may be disposed to surround the outer edge of the mask membrane MM disposed in each cell region 1710, for example.

A cell opening COP and the unit mask UM for masking at least a portion of the cell opening COP may be defined and disposed in each of the plurality of cell regions 1710 of the silicon substrate 1700.

The plurality of cell openings COP may penetrate the mask frame MF along a thickness direction (e.g., the third direction DR3) of the mask MK. The plurality of cell openings COP may be defined by etching a portion of the silicon substrate 1700 from the rear direction.

Each unit mask UM may include the mask membrane MM, and a mask opening OP may be defined in the mask membrane MM.

The mask opening OP of the mask membrane MM may be also referred to as “hole” or “mask hole.” The mask openings OP may penetrate the unit masks UM along the thickness direction (e.g., the third direction DR3) of the mask MK.

One unit mask UM may be used in the deposition process of one display panel 100. In the disclosure, the term “unit mask UM” may be replaced with a term such as a mask unit UM.

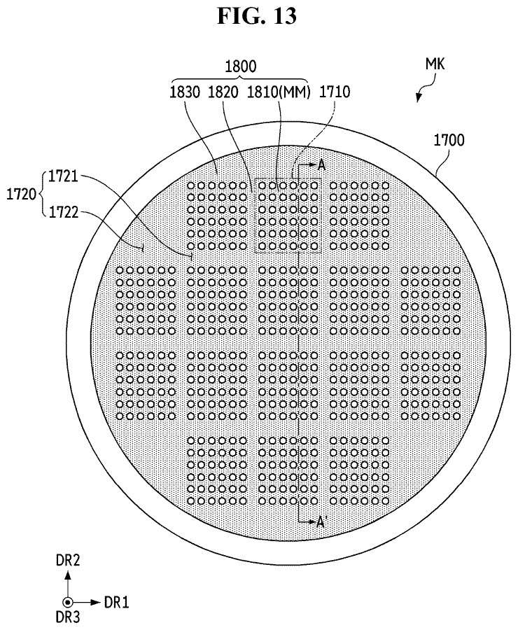

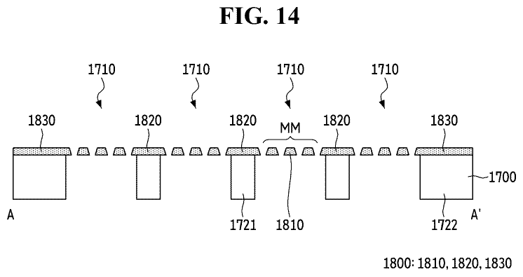

FIG. 13 is a schematic plan view of a comparative example of a mask. FIG. 14 is a cross-sectional view of the comparative example of a mask taken along line A-A′ shown in FIG. 13.

Referring to FIGS. 13 and 14, the mask MK according to the comparative example includes the substrate 1700 (e.g., 1700 of FIG. 12), and an inorganic film 1800 is disposed on the substrate 1700.

At least a portion of the inorganic film 1800 is patterned in each of the plurality of cell regions 1710 to form an inorganic film pattern 1810, and the inorganic film pattern 1810 constitutes the mask membrane MM of the mask MK. The mask membrane MM is formed by the inorganic film pattern 1810, which is a portion of the inorganic film 1800 formed on the substrate, and is disposed to correspond to the plurality of cell regions 1710, for example.

The mask membrane MM may include the inorganic film 1800, and the plurality of mask openings OP (refer to FIG. 11) may be defined in the mask membrane MM. The mask membrane MM may be exposed from the rear surface of the substrate 1700 through the cell opening COP (refer to FIG. 11) defined by etching the rear surface of the substrate 1700.

The mask lip region 1721 surrounding each cell region is disposed around the plurality of cell regions 1710. In addition, the outer frame region 1722 is disposed outside the entirety of the plurality of cell regions 1710. Dummy inorganic film patterns 1820 and 1830 are disposed as the remaining inorganic film 1800 in the mask lip region 1721 and a portion of the outer frame region 1722.

The dummy inorganic film patterns 1820 and 1830 include a first dummy inorganic film pattern 1820 disposed in the mask lip region 1721 and a second dummy inorganic film pattern 1830 disposed in a portion of the outer frame region 1722. The first dummy inorganic film pattern 1820 and the second dummy inorganic film pattern 1830 are deposited on the substrate so as to be continuous.

As such, in the mask MK according to the comparative example, the inorganic film 1800 covers most of the area on the substrate 1700 except for the plurality of cell regions 1710.

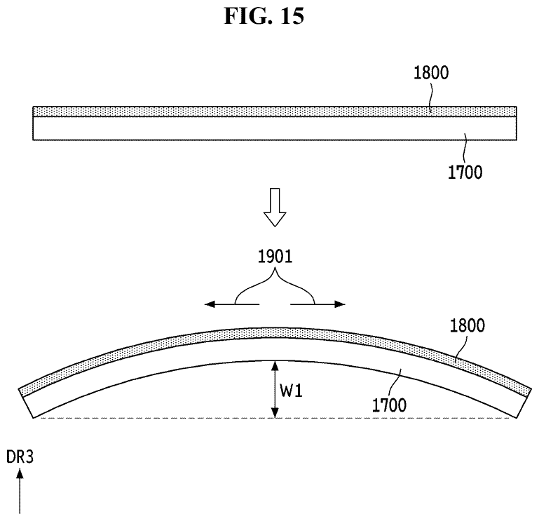

FIG. 15 is a conceptual diagram illustrating the warpage characteristic of the mask shown in FIG. 13.

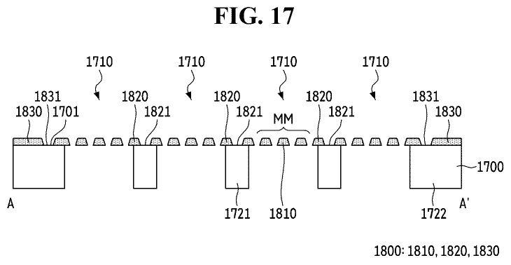

Referring to FIG. 15, the inorganic film 1800 deposited on the substrate 1700 (e.g., 1700 of FIG. 17) may be a material that exerts compressive stress 1901 (or tensile stress) on the substrate 1700. During the process of depositing the inorganic film 1800 on the substrate 1700 and patterning the deposited inorganic film 1800, a deviation in the coefficient of thermal expansion (“CTE”) between the substrate 1700 and the inorganic film 1800 occurs, for example. This deviation in the CTE causes the inorganic film 1800 to exert the compressive stress 1901 (or tensile stress) on the substrate 1700, which increases the bending and warpage value of the substrate 1700.

The bending of the substrate 1700 may cause defects such as tearing of the mask membrane MM, and therefore a method is required to reduce the bending, i.e., the warpage value, of the substrate 1700.

In the comparative example of FIG. 13, in the mask MK, the inorganic film 1800 covers most of the area on the substrate 1700 except for the plurality of cell regions 1710. The warpage of the substrate 1700 is proportional to the length or area of the thin film, e.g., the inorganic film 1800, deposited on the substrate 1700 that is continuous and uninterrupted. In the comparative example of FIG. 13, as the dummy inorganic film patterns 1820 and 1830 of the inorganic film 1800 are continuous in the mask lip region 1721 and the outer frame region 1722, the magnitude of stress exerted by the inorganic film 1800 on the substrate is relatively large. The mask MK according to the comparative example of FIG. 13 may have a warpage parameter corresponding to a first value W1, for example.

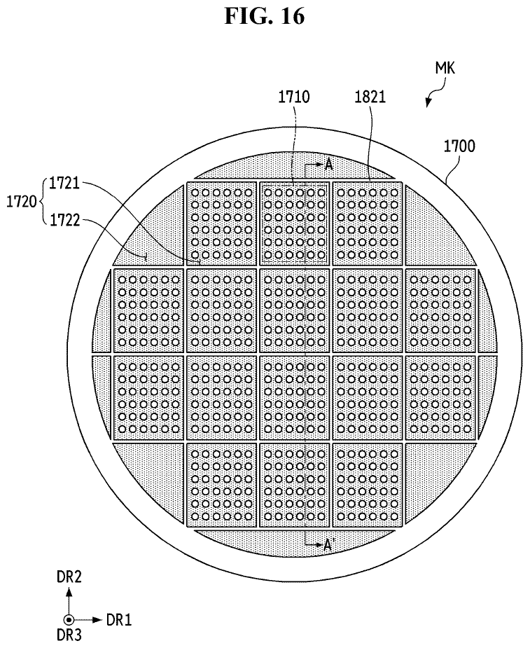

An embodiment of the disclosure includes design structures for improving the warpage of the substrate 1700 having the first value W1 in the comparative example of FIGS. 13 and 14. Hereinafter, an embodiment of the disclosure for reducing the warpage of the substrate 1700 will be described with reference to FIGS. 16 to 28.

FIG. 16 is a plan view of a mask. FIG. 17 is a cross-sectional view of the mask of an embodiment taken along line A-A′ shown in FIG. 16.

Unlike the comparative example shown in FIGS. 13 and 14, in the mask in an embodiment shown in FIGS. 16 and 17, the dummy inorganic film patterns 1820 and 1830 are segmented, thereby reducing the stress exerted by the inorganic film 1800 on the substrate and reducing the warpage of the mask MK.

Referring to FIGS. 16 and 17, the mask MK in an embodiment includes the substrate 1700 (e.g., 1700 of FIG. 12), and the inorganic film 1800 is disposed on the substrate 1700. The inorganic film 1800 is formed as a single film. In an embodiment, the inorganic film 1800 may be a single film including or consisting of at least one material selected from silicon (Si), silicon nitride (SiNx), silicon oxynitride (SiON), silicon oxide (SiOx), titanium oxide (TiOx), amorphous silicon (a-Si), and aluminum oxide (AlOx), for example.

At least a portion of the inorganic film 1800 is patterned in each of the plurality of cell regions 1710 to form an inorganic film pattern 1810, and the inorganic film pattern 1810 constitutes the mask membrane MM of the mask MK. In an embodiment, the mask membrane MM is formed by the inorganic film pattern 1810, which is a portion of the inorganic film 1800 formed on the substrate 1700, and is disposed to correspond to the plurality of cell regions 1710, for example.

The mask membrane MM may include the inorganic film 1800, and the plurality of mask openings OP (refer to FIG. 11) may be defined in the mask membrane MM. The mask membrane MM may be exposed from the rear surface of the substrate 1700 through the cell opening COP (refer to FIG. 11) defined by etching the rear surface of the substrate 1700.

The mask lip region 1721 surrounding each cell region 1710 is disposed around the plurality of cell regions 1710. In addition, the outer frame region 1722 is disposed outside the entirety of the plurality of cell regions 1710. Dummy inorganic film patterns 1820 and 1830 are disposed as the remaining inorganic film 1800 in the mask lip region 1721 and a portion of the outer frame region 1722.

The dummy inorganic film patterns 1820 and 1830 include the first dummy inorganic film pattern 1820 disposed in the mask lip region 1721 and the second dummy inorganic film pattern 1830 disposed in a portion of the outer frame region 1722. The first dummy inorganic film pattern 1820 and the second dummy inorganic film pattern 1830 are at least partially removed by a patterning process in the mask lip region 1721 and the outer frame region 1722, so that they are segmented rather than continuous.

In an embodiment, a lip opening 1821 exposing the surface of the substrate 1700 is defined in the first dummy inorganic film pattern 1820 disposed in the mask lip region 1721.

The lip opening 1821 is disposed to surround the plurality of cell regions. The lip opening 1821 is disposed in a straight line along the first direction DR1 in which the mask lip region extends or the second direction DR2 perpendicular to the first direction DR1.

In an embodiment, the lip opening 1821 includes a first lip opening 1821a extending in the first direction DR1 and a second lip opening 1821b extending in the second direction DR2 so as to intersect the first lip opening 1821a.

In an embodiment, an outer opening 1831 exposing the surface of the substrate 1700 is defined in the second dummy inorganic film pattern 1830 disposed in the outer frame region 1722.

In this way, in the mask MK in an embodiment, the dummy inorganic film patterns 1820 and 1830 are segmented, thereby reducing the stress exerted by the inorganic film 1800 on the substrate 1700 and reducing the warpage of the mask MK.

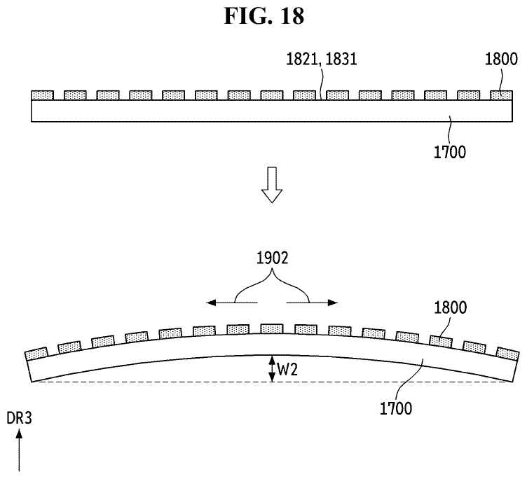

FIG. 18 is a conceptual diagram illustrating the warpage characteristic of the mask shown in FIG. 16.

Referring to FIGS. 16 to 18, in the mask MK in an embodiment, the dummy inorganic film patterns 1820 and 1830 are segmented, thereby reducing the stress exerted by the inorganic film 1800 on the substrate and reducing the warpage of the mask MK. In an embodiment, the lip opening 1821 exposing the surface of the substrate 1700 is defined in the first dummy inorganic film pattern 1820 disposed in the mask lip region 1721, for example. Further, the outer opening 1831 exposing the surface of the substrate 1700 is defined in the second dummy inorganic film pattern 1830 disposed in the outer frame region 1722.

Unlike the comparative example shown in FIG. 13, in the mask in an embodiment shown in FIGS. 16 to 18, the inorganic film 1800 may be divided into multiple segments due to interruptions by the lip opening 1821 and the outer opening 1831 in the mask lip region 1721 and the outer frame region 1722.

In the mask MK in an embodiment, the inorganic film 1800 deposited on the substrate 1700 is divided into a plurality of segments, and as they are segmented by the lip opening 1821 and the outer opening 1831, the stress exerted by the inorganic film 1800 on the substrate 1700 may be reduced, and the warpage of the mask MK may be reduced. In an embodiment, the warpage of the mask MK in an embodiment may have a second value W2 less than the first value W1 of FIG. 15, for example.

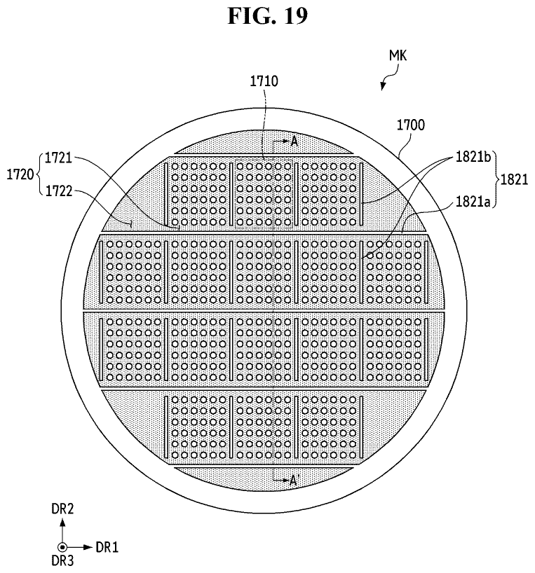

FIGS. 19 to 23 are plan views of a mask illustrating the shapes of a lip opening according to various embodiments. The embodiments of FIGS. 19 to 23 differ from the embodiment of FIGS. 16 and 17 in the shape of the lip opening 1821. Hereinafter, only the features of each of the embodiments of FIGS. 19 to 23 that differ from the embodiment of FIGS. 16 and 17 will be described.

Referring to FIG. 19, the mask in an embodiment includes the first dummy inorganic film pattern 1820 disposed in the mask lip region 1721, and the lip opening 1821 exposing the surface of the substrate 1700 in the mask lip region 1721 is defined in the first dummy inorganic film pattern 1820.

The lip opening 1821 is disposed to surround the plurality of cell regions 1710, and is disposed in a straight line along the first direction DR1 in which the mask lip region 1721 extends or the second direction DR2 perpendicular to the first direction DR1.

In the region where the first lip opening 1821a and the second lip opening 1821b intersect, the second lip opening 1821b is segmented. In addition, in the region where the first lip opening 1821a and the second lip opening 1821b intersect, the first lip opening 1821a is continuous.

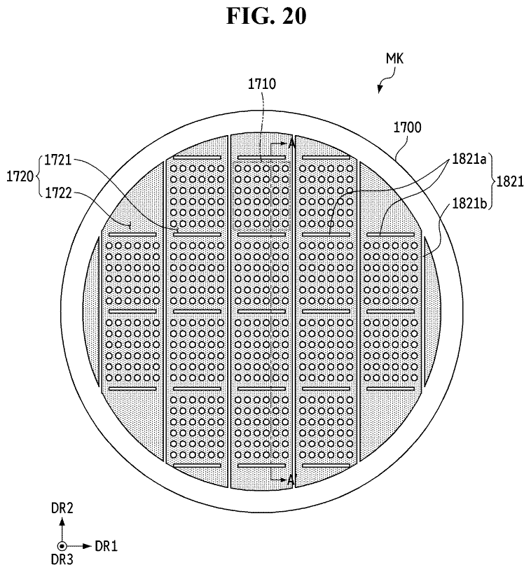

Referring to FIG. 20, the mask in an embodiment includes the first dummy inorganic film pattern 1820 disposed in the mask lip region 1721, and the lip opening 1821 exposing the surface of the substrate 1700 in the mask lip region 1721 is defined in the first dummy inorganic film pattern 1820.

The lip opening 1821 is disposed to surround the plurality of cell regions 1710, and is disposed in a straight line along the first direction DR1 in which the mask lip region 1721 extends or the second direction DR2 perpendicular to the first direction DR1.

In the region where the first lip opening 1821a and the second lip opening 1821b intersect, the first lip opening 1821a is segmented. In addition, in the region where the first lip opening 1821a and the second lip opening 1821b intersect, the second lip opening 1821b is continuous.

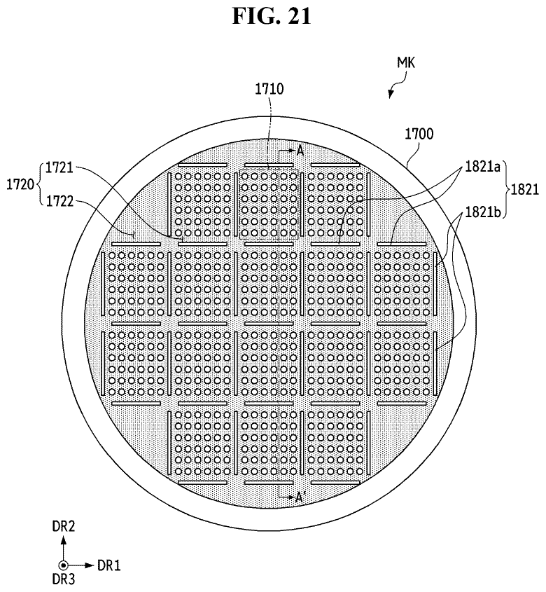

Referring to FIG. 21, the mask in an embodiment includes the first dummy inorganic film pattern 1820 disposed in the mask lip region 1721, and the lip opening 1821 exposing the surface of the substrate 1700 in the mask lip region 1721 is defined in the first dummy inorganic film pattern 1820.

The lip opening 1821 is disposed to surround the plurality of cell regions 1710, and is disposed in a straight line along the first direction DR1 in which the mask lip region 1721 extends or the second direction DR2 perpendicular to the first direction DR1.

In the region where the first lip opening 1821a and the second lip opening 1821b intersect, each of the first lip opening 1821a and the second lip opening 1821b is segmented.

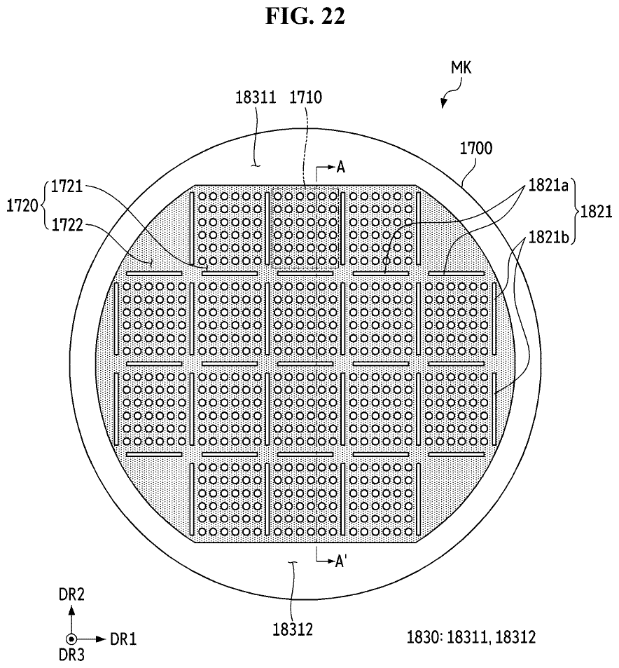

Referring to FIG. 22, the mask in an embodiment includes the first dummy inorganic film pattern 1820 disposed in the mask lip region 1721, and the lip opening 1821 exposing the surface of the substrate 1700 in the mask lip region 1721 is defined in the first dummy inorganic film pattern 1820.

The lip opening 1821 is disposed to surround the plurality of cell regions 1710, and is disposed in a straight line along the first direction DR1 in which the mask lip region 1721 extends or the second direction DR2 perpendicular to the first direction DR1.

A plurality of outer openings 18311 and 18312 may be defined in the second dummy inorganic film pattern 1830. In an embodiment, a first outer opening 18311 exposing the surface of the substrate 1700 is defined in the second dummy inorganic film pattern 1830 in a first outer frame region of the outer frame region 1722 next (adjacent) to one side of the substrate 1700, and a second outer opening 18312 exposing the surface of the substrate 1700 is defined in the second dummy inorganic film pattern 1830 in a second outer frame region of the outer frame region 1722 next (adjacent) to an opposite side of the substrate 1700, for example.

The first outer opening 18311 and the second outer opening 18312 have a symmetrical shape with respect to the center of the substrate 1700.

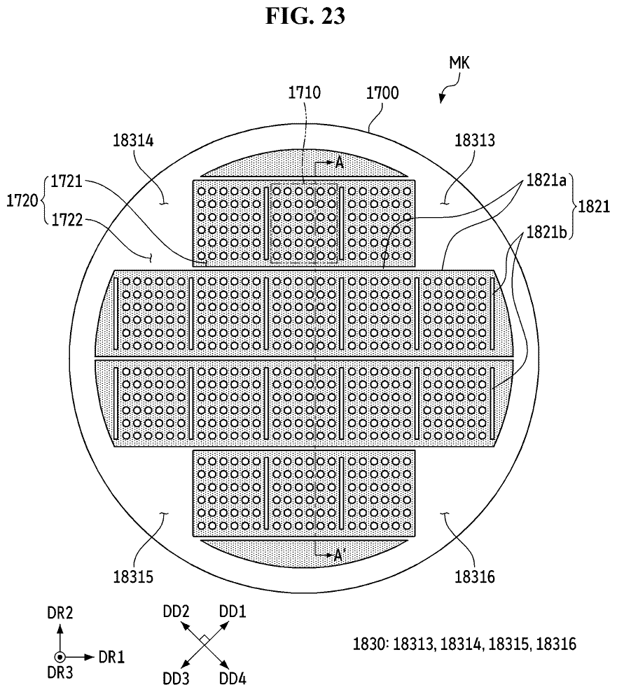

Referring to FIG. 23, the mask MK in an embodiment includes the first dummy inorganic film pattern 1820 disposed in the mask lip region 1721, and the lip opening 1821 exposing the surface of the substrate 1700 in the mask lip region 1721 is defined in the first dummy inorganic film pattern 1820.

The lip opening 1821 is disposed to surround the plurality of cell regions 1710, and is disposed in a straight line along the first direction DR1 in which the mask lip region 1721 extends or the second direction DR2 perpendicular to the first direction DR1.

A plurality of outer openings 18313, 18314, 18315 and 18316 may be defined in the second dummy inorganic film pattern 1830. In an embodiment, the second dummy inorganic film pattern 1830 defines a third outer opening 18313 exposing the surface of the substrate 1700 in a first edge region of the substrate 1700 disposed in the first diagonal direction DD1 between the first direction DR1 and the second direction DR2 from the center of the substrate 1700, a fourth outer opening 18314 exposing the surface of the substrate 1700 in a second edge region of the substrate 1700 disposed in the second diagonal direction DD2 perpendicular to the first diagonal direction DD1 from the center of the substrate 1700, a fifth outer opening 18315 exposing the surface of the substrate 1700 in a third edge region of the substrate 1700 disposed in a third diagonal direction DD3 opposite to the first diagonal direction DD1 from the center of the substrate 1700, and a sixth outer opening 18316 exposing the surface of the substrate 1700 in a fourth edge region of the substrate 1700 disposed in a fourth diagonal direction DD4 opposite to the second diagonal direction DD2 from the center of the substrate 1700, for example.

The third outer opening 18313 and the fifth outer opening 18315 have a symmetrical shape with respect to the center of the substrate 1700. In addition, the fourth outer opening 18314 and the sixth outer opening 18316 have a symmetrical shape with respect to the center of the substrate 1700.

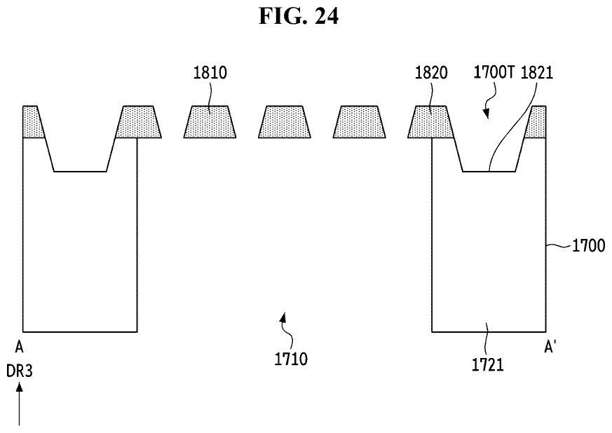

FIG. 24 is a schematic cross-sectional view of a mask in an embodiment further including a trench.

The embodiment of FIG. 24 differs from the embodiment of FIGS. 16 and 17 in that a trench 1700T is additionally defined in the mask lip region 1721 of the substrate 1700 in which the lip opening 1821 is disposed. Hereinafter, only the features of the embodiment of FIG. 24 that differ from the embodiment of FIGS. 16 and 17 will be described.

Referring to FIG. 24, the first dummy inorganic film pattern 1820 disposed in each of the cell regions 1710 next (adjacent) to each other is segmented by the lip opening 1821. Here, the trench 1700T is defined in the substrate 1700 by etching a portion of the substrate 1700 to a predetermined depth in the lip opening 1821.

In an embodiment, the trench 1700T of the substrate 1700 may be disposed along a direction in which the lip opening 1821 extends. The trench 1700T of the substrate 1700 may have a predetermined depth, and the depth thereof may be variously changed.

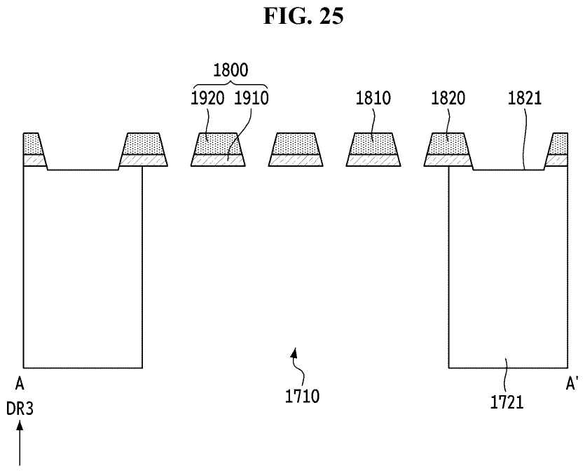

FIGS. 25 to 28 are schematic cross-sectional views of a mask according to various embodiments in which an inorganic film has a multilayer structure.

The embodiments of FIGS. 25 to 28 differ from the embodiment of FIGS. 16 and 17 in that the inorganic film has a multilayer structure.

By the embodiments of FIGS. 25 to 28, the inorganic film has a multilayer structure including a first inorganic film and a second inorganic film deposited on the first inorganic film. Each of the first inorganic film and the second inorganic film may include or consist of at least one material selected from silicon (Si), silicon nitride (SiNx), silicon oxynitride (SiON), silicon oxide (SiOx), titanium oxide (TiOx), amorphous silicon (a-Si), and aluminum oxide (AlOx). In an embodiment, the first inorganic film may include or consist of silicon oxy nitride (SiON), and the second inorganic film may include or consist of silicon nitride (SiNx), but the disclosure is not limited thereto.

Hereinafter, only the features of the embodiments of FIGS. 25 to 28 that differ from the embodiment of FIGS. 16 and 17 will be described.

Referring to FIG. 25, the inorganic film includes the first inorganic film deposited on the substrate 1700 and the second inorganic film deposited on the first inorganic film.

The mask membrane is formed on the substrate 1700. The mask membrane is formed by the inorganic film pattern that is a portion of the inorganic film including the first inorganic film and the second inorganic film on the first inorganic film. The mask membrane disposed to correspond to the plurality of cell regions 1710 includes the first inorganic film and the second inorganic film.

The inorganic film includes the dummy inorganic film pattern as the remaining portion except for the inorganic film pattern of the cell opening. The dummy inorganic film patterns include the first dummy inorganic film pattern 1820 disposed in the mask lip region 1721 and the second dummy inorganic film pattern 1830 disposed in a portion of the outer frame region 1722.

The lip opening 1821 exposing the surface of the substrate 1700 is defined in The first dummy inorganic film pattern 1820 by removing the first inorganic film and the second inorganic film in the mask lip region 1721.

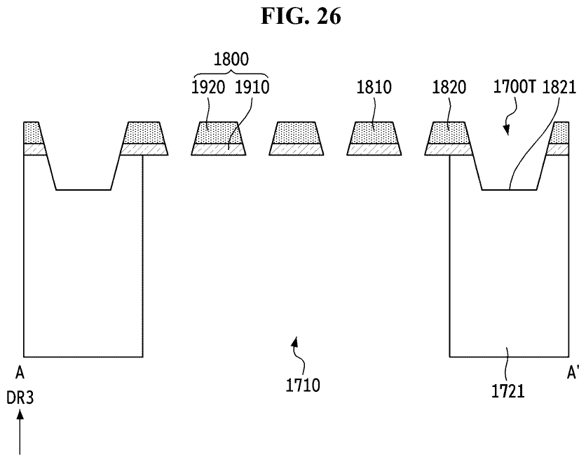

Referring to FIG. 26, the inorganic film 1800 includes a first inorganic film 1910 deposited on the substrate 1700, and a second inorganic film 1920 deposited on the first inorganic film 1910.

The mask membrane MM is formed on the substrate 1700. The mask membrane MM is formed by the inorganic film pattern that is a portion of the inorganic film 1800 including the first inorganic film 1910 and the second inorganic film 1920 on the first inorganic film 1910. The mask membrane MM disposed to correspond to the plurality of cell regions 1710 includes the first inorganic film 1910 and the second inorganic film 1920.

The inorganic film 1800 includes the dummy inorganic film patterns 1820 and 1830 as the remaining portions except for the inorganic film pattern 1810 of the cell opening COP.

The dummy inorganic film patterns 1820 and 1830 include a first dummy inorganic film pattern 1820 disposed in the mask lip region 1721 and a second dummy inorganic film pattern 1830 disposed in a portion of the outer frame region 1722.

The lip opening 1821 exposing the surface of the substrate 1700 is defined in The first dummy inorganic film pattern 1820 by removing the first inorganic film 1910 and the second inorganic film 1920 in the mask lip region 1721.

The substrate 1700 may further include the trench 1700T defined by etching a portion of the substrate 1700 to a predetermined depth in the lip opening 1821.

In an embodiment, the trench 1700T of the substrate 1700 may be disposed along a direction in which the lip opening 1821 extends. The trench 1700T of the substrate 1700 may have a predetermined depth, and the depth thereof may be variously changed.

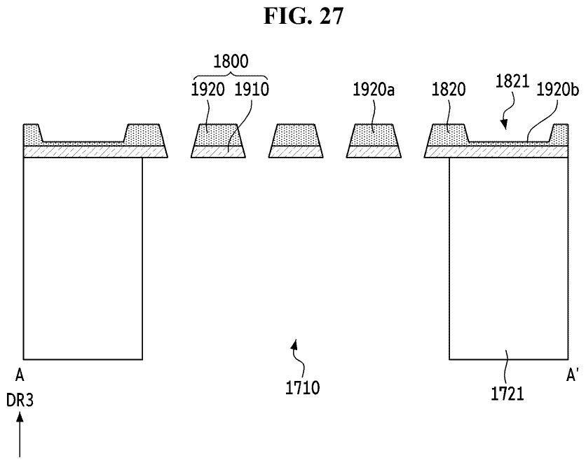

Referring to FIG. 27, the inorganic film 1800 includes the first inorganic film 1910 deposited on the substrate 1700, and the second inorganic film 1920 deposited on the first inorganic film 1910.

The mask membrane MM is formed on the substrate 1700. The mask membrane MM is formed by the inorganic film pattern that is a portion of the inorganic film 1800 including the first inorganic film 1910 and the second inorganic film 1920 on the first inorganic film 1910. The mask membrane MM disposed to correspond to the plurality of cell regions 1710 includes the first inorganic film 1910 and the second inorganic film 1920.

The inorganic film 1800 includes the dummy inorganic film patterns 1820 and 1830 as the remaining portions except for the inorganic film pattern 1810 of the cell opening COP.

The dummy inorganic film patterns 1820 and 1830 include a first dummy inorganic film pattern 1820 disposed in the mask lip region 1721 and a second dummy inorganic film pattern 1830 disposed in a portion of the outer frame region 1722.

The lip opening 1821 at which the second inorganic film 1920 has a stepped portion is defined in the first dummy inorganic film pattern 1820 by removing only a portion of the second inorganic film 1920 between the first inorganic film 1910 and the second inorganic film 1920 in the mask lip region 1721.

In an embodiment, the thickness of a second inorganic film 1920b exposed through the lip opening 1821 is less than the thickness of a second inorganic film 1920a disposed in the plurality of cell regions.

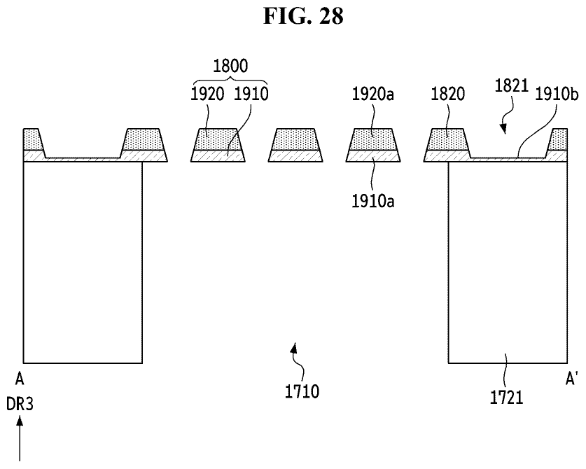

Referring to FIG. 28, the inorganic film 1800 includes the first inorganic film 1910 deposited on the substrate 1700, and the second inorganic film 1920 deposited on the first inorganic film 1910.

The mask membrane MM is formed on the substrate 1700. The mask membrane MM is formed by the inorganic film pattern that is a portion of the inorganic film 1800 including the first inorganic film 1910 and the second inorganic film 1920 on the first inorganic film 1910. The mask membrane MM disposed to correspond to the plurality of cell regions 1710 includes the first inorganic film 1910 and the second inorganic film 1920.

The inorganic film 1800 includes the dummy inorganic film patterns 1820 and 1830 as the remaining portions except for the inorganic film pattern 1810 of the cell opening COP.

The dummy inorganic film patterns 1820 and 1830 include a first dummy inorganic film pattern 1820 disposed in the mask lip region 1721 and a second dummy inorganic film pattern 1830 disposed in a portion of the outer frame region 1722.

In an embodiment, the lip opening 1821 exposing the surface of the first inorganic film 1910 is defined in the first dummy inorganic film pattern 1820 by removing only the second inorganic film 1920 between the first inorganic film 1910 and the second inorganic film 1920 in the mask lip region 1721. In this case, the thickness of a first inorganic film 1910b exposed through the lip opening 1821 is equal to the thickness of a first inorganic film 1910a disposed in the plurality of cell regions.

In another embodiment, the lip opening 1821 at which the first inorganic film 1910 has a stepped portion may be defined in the first dummy inorganic film pattern 1820 by removing a portion of the first inorganic film 1910 and the second inorganic film 1920 between the first inorganic film 1910 and the second inorganic film 1920 in the mask lip region 1721. In this case, the thickness of the first inorganic film 1910b exposed through the lip opening 1821 is less than the thickness of the first inorganic film 1910a disposed in the plurality of cell regions.

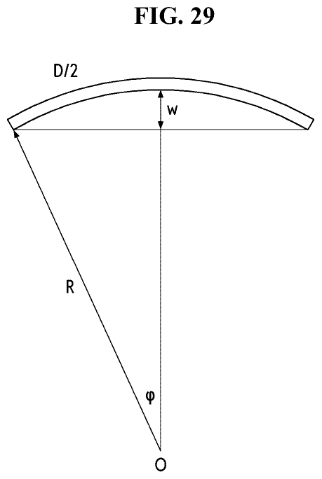

FIG. 29 is a conceptual diagram illustrating a warp characteristic of a mask.

Referring to FIG. 29, the warp characteristic of the mask may be as shown in Eq. (1):

$$W = ( {D}^{2} ) / ( 8 R ) \qquad ( 1 )$$

where W represents a warp characteristic value, D represents a wafer diameter, and R represents a radius of curvature. That is, the radius of curvature R is a distance between a center O of an imaginary circle corresponding to a curve of the wafer to a point on the circumference of the imaginary circle. Here, an angle φ may be defined between a line passing the center O of the imaginary circle and one end of the wafer and a line passing the center O of the imaginary circle and a center of the wafer.

Referring to Eq. (1), it may be seen that the warp characteristic value representing the bending characteristic of the mask is proportional to the value of D, which is a film formation diameter of a material deposited on the wafer.

In the mask MK according to the disclosure, as described with reference to FIGS. 16 to 18, the dummy inorganic film patterns 1820 and 1830 may be segmented, thereby reducing the value of D, which is a film formation diameter of a material deposited on the wafer. Accordingly, in the mask MK in an embodiment, the warp characteristic representing the bending characteristic of the mask may be reduced, and the bending and warpage of the mask may be reduced.

The display device according to the embodiment can be applied to various electronic devices. The electronic device according to one embodiment includes the display device described above and may further include modules or devices having additional functions in addition to the display device.

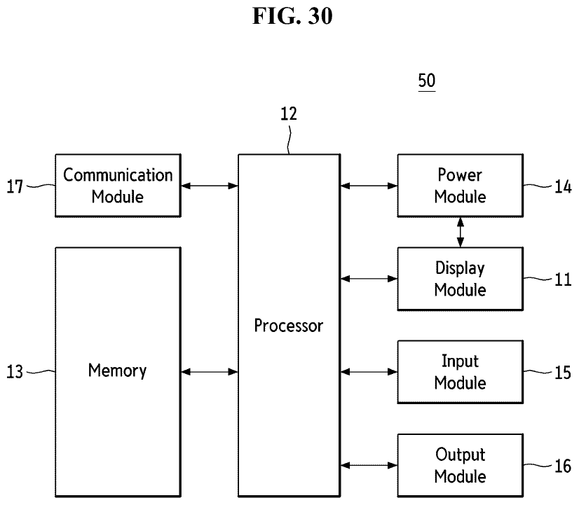

FIG. 30 is a block diagram of an electronic device according to one embodiment. Referring to FIG. 30, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

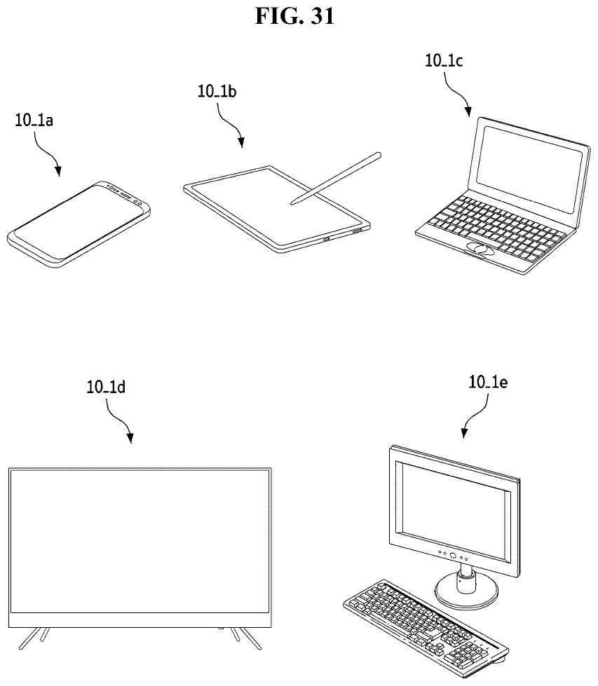

FIGS. 31, 32, and 33 are schematic diagrams of electronic devices according to various embodiments. FIGS. 31 to 33 illustrate examples of various electronic devices to which the display device according to the embodiments is applied.

FIG. 31 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

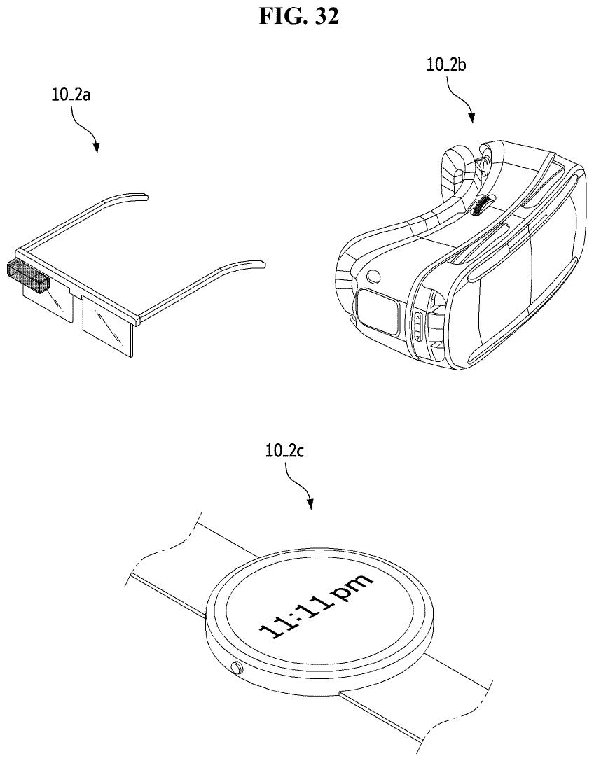

FIG. 32 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

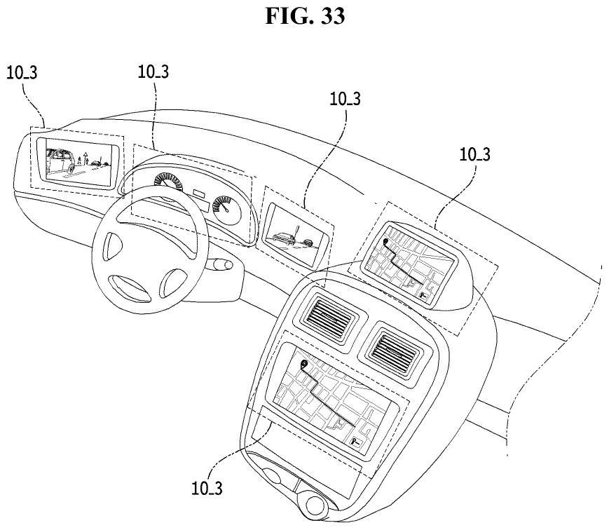

The smart watch 10_2c includes a biometric sensor as an input device, and may provide biometric information recognized by the biometric sensor to the user through the display module. FIG. 33 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the disclosure belongs that the disclosure may be implemented in other forms without changing the technical spirit or essential features of the disclosure. Therefore, it is to be understood that the embodiments described above are illustrative rather than being restrictive in all features. It is to be understood that the scope of the disclosure are defined by the claims rather than the detailed description described above and all modifications and alterations derived from the claims and their equivalents fall within the scope of the disclosure.

What is claimed is:

1. A deposition mask comprising:
a substrate comprising:
a plurality of cell regions;
a mask lip region partitioning the plurality of cell regions; and
an outer frame region disposed at an outer edge of the plurality of cell regions;
a mask membrane defined by an inorganic film pattern which is a portion of an inorganic film disposed on the substrate and corresponding to the plurality of cell regions; and
a dummy inorganic film pattern which is a remaining portion of the inorganic film except for the inorganic film pattern, the dummy inorganic film pattern comprising:
a first dummy inorganic film pattern which is disposed in the mask lip region and in which a lip opening exposing a surface of the substrate in the mask lip region is defined; and
a second dummy inorganic film pattern disposed in a portion of the outer frame region.

2. The deposition mask of claim 1, wherein the lip opening surrounds the plurality of cell regions, and is disposed in a straight line along a first direction in which the mask lip region extends or a second direction perpendicular to the first direction.

3. The deposition mask of claim 2, wherein the lip opening comprises:
a first lip opening extending in the first direction; and
a second lip opening extending in the second direction and intersecting the first lip opening.

4. The deposition mask of claim 3, wherein in a region where the first lip opening and the second lip opening intersect, the first lip opening is segmented, and
in a region where the first lip opening and the second lip opening intersect, the second lip opening is continuous.

5. The deposition mask of claim 3, wherein in a region where the first lip opening and the second lip opening intersect, the second lip opening is segmented, and
in a region where the first lip opening and the second lip opening intersect, the first lip opening is continuous.

6. The deposition mask of claim 3, wherein in a region where the first lip opening and the second lip opening intersect, each of the first lip opening and the second lip opening is segmented.

7. The deposition mask of claim 1, wherein the second dummy inorganic film pattern defines:
a first outer opening exposing the surface of the substrate in a first outer frame region of the outer frame region next to one side of the substrate; and
a second outer opening exposing the surface of the substrate in a second outer frame region of the outer frame region next to an opposite side of the substrate, and
the first outer opening and the second outer opening have a symmetrical shape with respect to a center of the substrate.

8. The deposition mask of claim 2, wherein the second dummy inorganic film pattern defines:
a third outer opening exposing the surface of the substrate in a first edge region of the substrate disposed in a first diagonal direction between the first direction and the second direction from a center of the substrate;
a fourth outer opening exposing the surface of the substrate in a second edge region of the substrate disposed in a second diagonal direction perpendicular to the first diagonal direction from the center of the substrate;
a fifth outer opening exposing the surface of the substrate in a third edge region of the substrate disposed in a third diagonal direction opposite to the first diagonal direction from the center of the substrate; and
a sixth outer opening exposing the surface of the substrate in a fourth edge region of the substrate disposed in a fourth diagonal direction opposite to the second diagonal direction from the center of the substrate,
the third outer opening and the fifth outer opening have a symmetrical shape with respect to the center of the substrate, and
the fourth outer opening and the sixth outer opening have a symmetrical shape with respect to the center of the substrate.

9. The deposition mask of claim 1, wherein the inorganic film pattern disposed in each of cell regions next to each other among the plurality of cell regions is segmented by the lip opening.

10. The deposition mask of claim 1, wherein the substrate further comprises a trench defined in the substrate and having a predetermined depth in the lip opening.

11. The deposition mask of claim 1, wherein the inorganic film is a single film.

12. The deposition mask of claim 1, wherein the inorganic film comprises a first inorganic film deposited on the substrate, and a second inorganic film deposited on the first inorganic film.

13. The deposition mask of claim 1, wherein the inorganic film pattern is a portion of an inorganic film comprising a first inorganic film disposed on the substrate and a second inorganic film on the first inorganic film, and corresponding to the plurality of cell regions.

14. The deposition mask of claim 1, wherein the dummy inorganic film pattern comprising:
a first dummy inorganic film pattern which is disposed in the mask lip region and in which a lip opening exposing the surface of the first inorganic film is defined; and
a second dummy inorganic film pattern disposed in a portion of the outer frame region.

15. A manufacturing method for forming a display panel pattern using a deposition mask, the method comprising:
allowing a material vaporized from a deposition source to pass through the deposition mask and be deposited on a display panel,
wherein the deposition mask comprises:
a substrate comprising:
a plurality of cell regions;
a mask lip region partitioning the plurality of cell regions; and
an outer frame region disposed at an outer edge of the plurality of cell regions;
a mask membrane defined by an inorganic film pattern which is a portion of an inorganic film formed on the substrate and corresponding to the plurality of cell regions; and
a dummy inorganic film pattern which is a remaining portion of the inorganic film except for the inorganic film pattern, the dummy inorganic film pattern comprising:
a first dummy inorganic film pattern which is disposed in the mask lip region and in which a lip opening exposing a surface of the substrate in the mask lip region; and
a second dummy inorganic film pattern disposed in a portion of the outer frame region.

16. The manufacturing method of claim 15, wherein the lip opening surrounds the plurality of cell regions, and is disposed in a straight line along a first direction in which the mask lip region extends or a second direction perpendicular to the first direction.

17. The manufacturing method of claim 16, wherein the lip opening comprises:
a first lip opening extending in the first direction; and
a second lip opening extending in the second direction and intersecting the first lip opening.

18. The manufacturing method of claim 17, wherein in a region where the first lip opening and the second lip opening intersect, the first lip opening is segmented, and
in a region where the first lip opening and the second lip opening intersect, the second lip opening is continuous.

19. The manufacturing method of claim 17, wherein in a region where the first lip opening and the second lip opening intersect, the second lip opening is segmented, and
in a region where the first lip opening and the second lip opening intersect, the first lip opening is continuous.

20. An electronic device comprising:
a display panel,
wherein the display panel is manufactured by a deposition mask,
wherein the deposition mask comprises:
a substrate comprising:
a plurality of cell regions;
a mask lip region partitioning the plurality of cell regions; and
an outer frame region disposed at an outer edge of the plurality of cell regions;
a mask membrane defined by an inorganic film pattern which is a portion of an inorganic film disposed on the substrate and corresponding to the plurality of cell regions; and
a dummy inorganic film pattern which is a remaining portion of the inorganic film except for the inorganic film pattern, the dummy inorganic film pattern comprising:
a first dummy inorganic film pattern which is disposed in the mask lip region and in which a lip opening exposing a surface of the substrate in the mask lip region is defined; and
a second dummy inorganic film pattern disposed in a portion of the outer frame region.
